(19) United States
(12) Patent Application Publication
(10) Pub. No.: US 2024/0259486 A1
(43) Pub. Date: Aug. 1, 2024

(54) DISPLAY DEVICE

(71) Applicant: Samsung Display Co., Ltd., Yongin-Si (KR)

(72) Inventors: JONGDEOK PARK, Yongin-si (KR); WON-SEOK KIM, Yongin-si (KR); Intae SON, Yongin-si (KR); JAESUK YOO, Yongin-si (KR); KANG-WOO LEE, Yongin-si (KR); Dasong LEE, Yongin-si (KR)

(21) Appl. No.: 18/524,277

(22) Filed: Nov. 30, 2023

(30) Foreign Application Priority Data
Jan. 30, 2023 (KR) 10-2023-0012092

(51) Int. Cl. H04M 1/02

(52) U.S. Cl. CPC H04M 1/0222; H04M 1/0266; H04M 2250/22

(57) ABSTRACT

A display device includes a display module. An adhesive member is disposed directly on the display module. A window is disposed directly on the adhesive member. The adhesive member includes a first adhesive layer disposed adjacent to the display module and having a first storage modulus at −20° C. A second adhesive layer is disposed directly on the first adhesive layer and has a second storage modulus at −20° ° C. The second storage modulus is greater than the first storage modulus.

### CROSS-REFERENCE TO RELATED APPLICATIONS

This application claims priority under 35 U.S.C. § 119 to Korean Patent Application No. 10-2023-0012092, filed on Jan. 30, 2023 in the Korean Intellectual Property office, the disclosure of which is incorporated by reference in its entirety herein.

### 1. TECHNICAL FIELD

The present disclosure herein relates to a display device including an adhesive member. More particularly, the present disclosure herein relates to a display device including an adhesive member having a plurality of adhesive layers.

### 2. DISCUSSION OF RELATED ART

Display modules using a light emitting diode (LED), an organic electroluminescence (organic EL), and the like are used in various display devices. The display modules are formed of a plurality of discrete members such as a plurality of optical functional films and a protective panel. An optically clear adhesive (OCA) and optically clear resin (OCR) may be provided in voids of each layer to increase adhesion therebetween.

Recently, stacked structures and shapes of members included in a display device have been diversified. Studies are being conducted on various types of adhesive members applicable to such a display device.

### SUMMARY

The present disclosure provides a display device with increased impact resistance.

According to an embodiment of the present disclosure, a display device includes a display module. An adhesive member is disposed directly on the display module. A window is disposed directly on the adhesive member. The adhesive member includes a first adhesive layer disposed adjacent to the display module and having a first storage modulus at −20° C. A second adhesive layer is disposed directly on the first adhesive layer and has a second storage modulus at −20° C. The second storage modulus is greater than the first storage modulus.

In an embodiment, the first storage modulus at −20° C. is in a range of about 150 KPa to about 350 KPa.

In an embodiment, the second storage modulus at −20° C. is in a range of about 8,500 KPa to about 25,000 KPa.

In an embodiment, the adhesive member has a thickness in a range of about 150 μm to about 200 μm.

In an embodiment, the first adhesive layer has a thickness in a range of about 50 μm to about 100 μm.

In an embodiment, the second adhesive layer has a thickness in a range of about 50 μm to about 150 μm.

In an embodiment, the second adhesive layer is disposed directly on the first adhesive layer.

In an embodiment, the display module includes a display panel, and an input-sensing unit disposed on the display panel. The adhesive member is disposed directly on the input-sensing unit.

In an embodiment, an impact absorbing layer is disposed below the display panel.

In an embodiment, the adhesive member further includes a third adhesive layer disposed between the second adhesive layer and the window and having a third storage modulus at −20° C. The third storage modulus is less than the second storage modulus.

In an embodiment, the third storage modulus at −20° C. is in a range of about 150 KPa to about 350 KPa.

In an embodiment, the first adhesive layer has a thickness in a range of about 50 μm to about 75 μm, the second adhesive layer has a thickness in a range of about 50 μm to about 100 μm, and the third adhesive layer has a thickness in a range of about 50 μm to about 75 μm.

In an embodiment, third adhesive layer is disposed directly on the second adhesive layer.

In an embodiment, the display device does not include a polarizing plate.

In an embodiment, the first adhesive layer and the second adhesive layer each have a loss tangent greater than or equal to about 1.

According to an embodiment of the present disclosure, a display device includes a folding region that is foldable with respect to a virtual folding axis extending in a first direction, and a first non-folding region and a second non-folding region that are spaced apart from each other in a second direction perpendicular to the first direction with the folding region therebetween. The display device includes a display module including a display panel. An adhesive member disposed directly on the display module. A window disposed directly on the adhesive member. The adhesive member includes a first adhesive layer adjacent to the display module and having a first storage modulus at −20° C., and a second adhesive layer disposed directly on the first adhesive layer and having a second storage modulus at −20° C. The second storage modulus is greater than the first storage modulus.

In an embodiment, an input sensing layer is disposed between the display panel and the adhesive member. The adhesive member is disposed directly on the input sensing layer.

In an embodiment, the first storage modulus at −20° ° C. is in a range of about 150 KPa to about 350 KPa.

In an embodiment, the second storage modulus at −20° C. is in a range of about 8,500 KPa to about 25,000 KPa.

In an embodiment, the adhesive member has a thickness in a range of about 150 μm to about 200 μm, the first adhesive layer has a thickness in a range of about 50 μm to about 100 μm, and the second adhesive layer has a thickness in a range of about 50 μm to about 150 μm.

In an embodiment, the adhesive member further includes a third adhesive layer disposed between the second adhesive layer and the window and having a third storage modulus at −20° C. The third storage modulus is less than the second storage modulus. The third adhesive layer is disposed directly on the second adhesive layer.

In an embodiment, the third storage modulus at −20° C. is in a range of about 150 KPa to about 350 KPa.

In an embodiment, the first adhesive layer has a thickness in a range of about 50 μm to about 75 μm, the second adhesive layer has a thickness in a range of about 50 μm to about 100 μm, and the third adhesive layer has a thickness in a range of about 50 μm to about 75 μm.

### BRIEF DESCRIPTION OF THE DRAWINGS

The accompanying drawings are included to provide a further understanding of embodiments of the present disclosure, and are incorporated in and constitute a part of this specification. The drawings illustrate embodiments of the present disclosure and, together with the description, serve to explain principles of the present disclosure. In the drawings:

FIG. 1 is a perspective view illustrating a display device according to an embodiment of the present disclosure;

FIG. 2A is a perspective view illustrating an unfolded state of the display device according to an embodiment of the present disclosure;

FIG. 2B is a perspective view illustrating that the display device illustrated in FIG. 2A is being in-folded according to an embodiment of the present disclosure;

FIG. 2C is a perspective view illustrating that the display device illustrated in FIG. 2A is being out-folded according to an embodiment of the present disclosure;

FIG. 3A is a perspective view illustrating an unfolded state of the display device according to an embodiment of the present disclosure;

FIG. 3B is a perspective view illustrating that the display device illustrated in FIG. 3A is being in-folded according to an embodiment of the present disclosure;

FIG. 3C is a perspective view illustrating that the display device illustrated in FIG. 3A is being out-folded according to an embodiment of the present disclosure;

FIG. 4 is an exploded perspective view of a display device according to an embodiment of the present disclosure;

FIG. 5 is a cross-sectional view of a display device according to an embodiment of the present disclosure;

FIG. 6 is a view schematically illustrating a display device according to an embodiment of the present disclosure;

FIG. 7 is a view schematically illustrating a display device according to an embodiment of the present disclosure;

FIG. 8A is a view schematically illustrating a ball that is dropped onto a display module;

FIG. 8B is a view schematically illustrating a ball that is dropped onto a test display device according to an Example according to an embodiment of the present disclosure;

FIG. 8C is a view schematically illustrating a ball that is dropped onto a test display device according to a Comparative Example;

FIG. 9A is a view illustrating the amount of change in internal energy of a test display device according to an Example before and after a ball drop according to an embodiment of the present disclosure;

FIG. 9B is a view illustrating the amount of change in internal energy of a test display device according to a Comparative Example before and after a ball drop;

FIG. 10A is a view illustrating an undeformed adhesive member before a ball drop according to an embodiment of the present disclosure; and

FIG. 10B is a view illustrating a deformed adhesive member after a ball drop according to an embodiment of the present disclosure.

### DETAILED DESCRIPTION OF EMBODIMENTS

The present disclosure may be implemented in various modifications and have various forms and non-limiting embodiments are illustrated in the drawings and described in detail in the text. It is to be understood, however, that the present disclosure is not intended to be limited to the particular forms disclosed, but on the contrary, is intended to cover all modifications, equivalents, and alternatives falling within the spirit and scope of the present disclosure.

It will be understood that when an element (or a region, a layer, a portion, or the like) is referred to as “being on”, “connected to” or “coupled to” another element, it may be directly disposed on, connected or coupled to the other element, or intervening elements may be disposed therebetween. When an element (or a region, a layer, a portion, or the like) is referred to as “being directly on”, “directly connected to” or “directly coupled to” another element, no intervening elements may be disposed therebetween.

Like reference numerals or symbols refer to like elements throughout. Also, in the drawings, the thicknesses, ratios, and dimensions of the elements may be exaggerated for effective description of the technical contents. The term “and/or” includes all of one or more combinations which may be defined by related elements.

Although the terms first, second, etc. may be used to describe various elements, these elements should not be limited by these terms. These terms are only used to distinguish one element from another element. For example, a first element may be referred to as a second element, and similarly, a second element may also be referred to as a first element without departing from the scope of the present disclosure. The singular forms include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described with respect to the directions indicated in the drawings.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, a display device according to an embodiment of the present disclosure will be described with reference to the drawings.

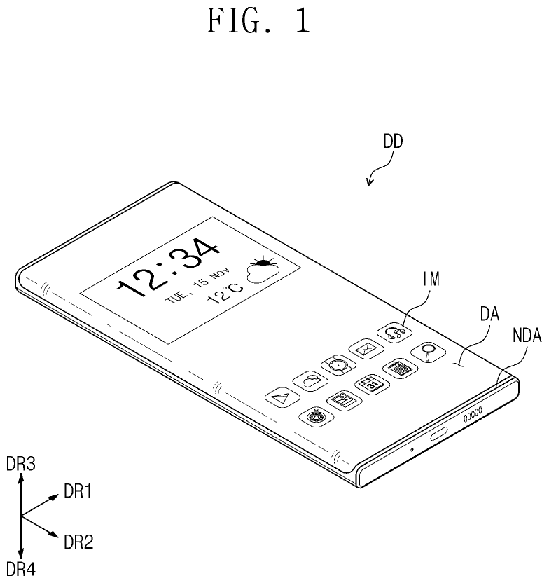

FIG. 1 is a perspective view illustrating a display device according to an embodiment.

A display device DD according to an embodiment illustrated in FIG. 1 may be a device activated in response to an electrical signal. For example, in some embodiments the display device DD may be a personal computer, a laptop computer, a personal digital terminal, a game console, a portable electronic device, a television, a monitor, an external billboard, a car navigation system, or a wearable device. However, embodiments of the present disclosure are not necessarily limited thereto. In FIG. 1, the display device DD is illustrated as a mobile phone for convenience of explanation.

The display device DD according to an embodiment may display an image IM through a display region DA. In an embodiment, the display region DA may include a flat surface extending in a plane defined in a first direction axis DR1 and a second direction axis DR2. In an embodiment, the display region DA may include a curved surface which is bent from at least one side of the flat surface defined by the first direction axis DR1 and the second direction axis DR2. FIG. 1 illustrates that the display device DD according to an embodiment includes two curved surfaces which are respectively bent from two sides of the flat surface defined by the first direction axis DR1 and the second direction axis DR2. However, embodiments of the present disclosure are not necessarily limited thereto and the shape of the display region DA may vary. For example, in an embodiment the display region DA may include only a flat surface extending in a plane defined by the first direction axis DR1 and the second direction axis DR2, and the display region DA may further include four curved surfaces that are respectively bent from at least two sides, for example, four sides of the flat surface defined by the first direction axis DR1 and the second direction axis DR2.

In FIG. 1 and the following drawings, the first direction axis DR1 to a fourth direction axis DR4 are illustrated. The directions indicated by the first to fourth direction axes DR1, DR2, DR3, and DR4 illustrated herein may have a relative concept and thus may be changed to other directions. In addition, the directions indicated by the first to fourth direction axes DR1, DR2, DR3, and DR4 may be described as first to fourth directions, and the same reference numerals or symbols may be used. In an embodiment, the first direction axis DR1 may be perpendicular to the second direction axis DR2, and the third direction axis DR3 may be a normal direction of the plane defined by the first direction axis DR1 and the second direction axis DR2. The third direction axis DR3 and the fourth direction axis DR4 may extend in opposite directions from each other.

A thickness direction of the display device DD may be parallel to a third direction axis DR3 that is a normal direction of a plane defined by the first direction axis DR1 and the second direction axis DR2. In this specification, a front surface (e.g., a top, top surface, upper portion) and a rear surface (e.g., a bottom, bottom surface, lower portion) of each member constituting the display device DD may be spaced apart from each other in the third direction axis DR3. In addition, in this specification, a front surface (e.g., a top, top surface, upper portion) means a surface (e.g., a direction) adjacent to the surface on which the image IM is displayed, and the rear surface (e.g., a bottom, bottom surface, lower portion) means a surface (e.g., a direction) spaced apart from the surface on which the image IM is displayed.

A non-display region NDA may be adjacent to the display region DA (e.g., in the first and/or second directions DR1, DR1). The non-display region NDA may surround the display region DA. Accordingly, the shape of the display region DA may be defined substantially by the non-display region NDA. However, embodiments of the present disclosure are not necessarily limited thereto, and the non-display region NDA may be disposed adjacent to only one side of the display region DA or omitted in some embodiments. The display region DA is provided in various shapes and is not necessarily limited to any one shape.

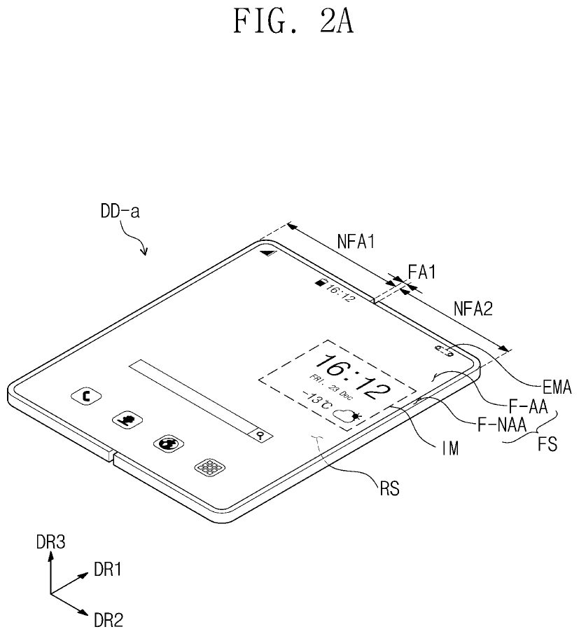

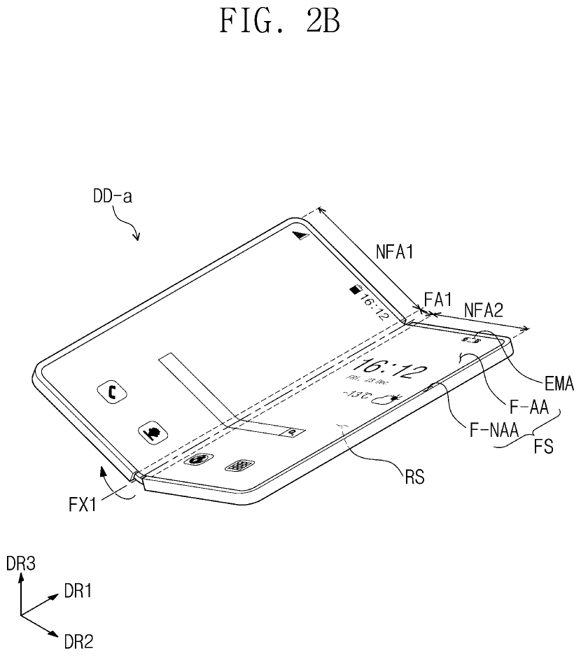

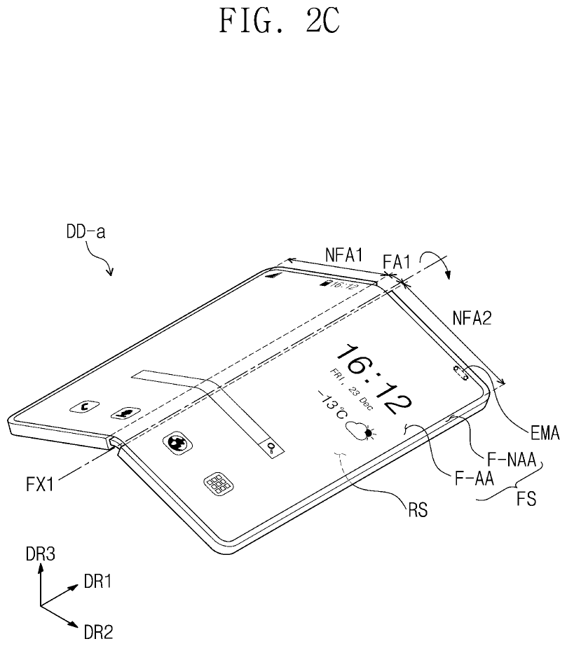

FIG. 2A is a perspective view illustrating an unfolded state of the display device according to an embodiment. FIG. 2B is a perspective view illustrating that the display device illustrated in FIG. 2A is being in-folded. FIG. 2C is a perspective view illustrating that the display device illustrated in FIG. 2A is being out-folded.

A display device DD-a according to an embodiment may be activated in response to an electrical signal. For example, in an embodiment the display device DD-a may be a mobile phone, a tablet PC, a car navigation system, a game console, or a wearable device. However, embodiments of the present disclosure are not necessarily limited thereto. In this specification, FIG. 2A, etc., illustrates that the display device DD-a is a mobile phone for convenience of explanation.

Referring to FIGS. 2A to 2C, the display device DD-a according to an embodiment may include a first display surface FS extending in a plane defined in the first direction axis DR1 and the second direction axis DR2 crossing the first direction axis DR1. The display device DD-a may display an image IM to a user through the first display surface FS. In the embodiment of FIG. 2A, the image IM is software application icons and a clock, temperature and calendar window. However embodiments of the present inventive concepts are not necessarily limited thereto and the image IM may be various different subject matter. The display device DD-a according to an embodiment may display the image IM, in the third direction axis DR3, through the first display surface FS parallel to each of the first direction axis DR1 and the second direction axis DR2. In this specification, a front surface (e.g., a top surface) and a rear surface (e.g., a bottom surface) of each member are defined with respect to the direction in which the image IM is displayed. The front and rear surfaces are opposite to each other in the third direction axis DR3, and the normal direction of each of the front and rear surfaces may be parallel to the third direction axis DR3.

The display device DD-a according to an embodiment may include the first display surface FS and a second display surface RS. The first display surface FS may include an active region F-AA and a peripheral region F-NAA. In an embodiment, an electronic module region EMA may be included in the active region F-AA. The electronic module region EMA may not be included in the peripheral region F-NAA. The second display surface RS may be defined as a surface that faces at least a portion of the first display surface FS. For example, the second display surface RS may be defined as a portion of the rear surface of the display device DD-a.

The display device DD-a according to an embodiment may sense an external input applied from the outside. The external input may include various types of inputs provided from the outside of the display device DD-a. For example, in an embodiment the external input may include not only a touch by a part of the user's body such as a hand but also an external input, such as hovering, applied when approaching the display device DD-a or becoming adjacent to the display device DD-a within a predetermined distance. In addition, the external input may be various types, such as force, pressure, temperature, and light. However, embodiments of the present disclosure are not necessarily limited thereto.

In FIG. 2A and the following drawings, the first direction axis DR1 to the third direction axis DR3 are illustrated. The directions indicated by the first to third direction axes DR1, DR2, and DR3 illustrated herein may have a relative concept and thus may be changed to other directions. In addition, the directions indicated by the first to third direction axes DR1, DR2, and DR3 may be referred to as first to third directions, and may thus be denoted as the same reference numerals or symbols.

The active region F-AA of the display device DD-a may be activated in response to an electrical signal. The display device DD-a according to an embodiment may display an image IM through the active region F-AA. Also, various types of external inputs may be sensed in the active region F-AA. The peripheral region F-NAA is adjacent to the active region F-AA (e.g., in the first and or second directions DR1, DR2). In an embodiment, the peripheral region F-NAA may have a predetermined color. The peripheral region F-NAA may surround the active region F-AA. Accordingly, the shape of the active region F-AA may be defined substantially by the peripheral region F-NAA. However, embodiments of the present disclosure are not necessarily limited thereto, and the peripheral region F-NAA may be disposed adjacent to only one side of the active region F-AA or may be omitted in some embodiments. The display device DD-a according to an embodiment of the present disclosure may have active regions having various shapes, and is not necessarily limited to an embodiment shown in the drawings.

The display device DD-a may include a folding region FA1 and first and second non-folding regions NFA1 and NFA2. In an embodiment, the first and second non-folding regions NFA1 and NFA2 may be disposed adjacent to the folding region FA1 (e.g., in the second direction DR2) with the folding region FA1 therebetween. The display device DD-a according to an embodiment may include a first non-folding region NFA1 and a second non-folding region NFA2 which are disposed to be spaced apart from each other in the direction of the second direction axis DR2 with the folding region FA1 therebetween. For example, the first non-folding region NFA1 may be disposed on a first side of the folding region FA1 along the second direction DR2, and the second non-folding region NFA2 may be disposed on an opposite second side of the folding region FA1 in the second direction DR2.

FIGS. 2A to 2C illustrate an embodiment of the display device DD-a including one folding region FA1. However, embodiments of the present disclosure are not necessarily limited thereto, and a plurality of folding regions may be defined in the display device DD-a and may be variously arranged with respect to a plurality of non-folding regions. For example, a display device according to an embodiment may include two or more folding regions, and may also include three or more non-folding regions with the folding regions disposed respectively therebetween.

Referring to FIG. 2B, the display device DD-a according to an embodiment may be folded with respect to the first folding axis FX1. The first folding axis FX1 is a virtual folding axis extending in the direction of the first direction axis DR1. In an embodiment, the first folding axis FX1 may be parallel to the relatively long-side direction of the display device DD-a. The first folding axis FX1 may extend in the first direction axis DR1 on the first display surface FS.

The display device DD-a may be folded with respect to the first folding axis FX1 and changed into an in-folded state in which in the first display surface FS, one region overlapping the first non-folding region NFA1 and the other region overlapping the second non-folding region NFA2 face each other.

In the display device DD-a according to an embodiment, the second display surface RS may be visible to the user in the in-folded state. The second display surface RS may further include an electronic module region where electronic modules including various components are disposed. However, embodiments of the present disclosure are not necessarily limited to any one embodiment.

Referring to FIG. 2C, the display device DD-a according to an embodiment may be folded with respect to the first folding axis FX1 and changed into an out-folded state in which in the second display surface RS, one region overlapping the first non-folding region NFA1 and the other region overlapping the second non-folding region NFA2 face each other.

However, embodiments of the present disclosure are not necessarily limited thereto, and the display device may be folded with respect to a plurality of folding axes so that portions of each of the first display surface FS and the second display surface RS face each other, and the number of folding axes and the corresponding number of non-folding regions may vary.

Various electronic modules may be disposed in the electronic module region EMA. For example, in an embodiment the electronic module included in the electronic module region EMA may include at least one of a camera, a speaker, a light detection sensor, or a heat detection sensor. The electronic module region EMA may sense an external subject received through the first or second display surfaces FS and RS or may provide sound signals such as voice to the outside through the first or second display surfaces FS and RS. The electronic module may include a plurality of components. However, embodiments of the present disclosure are not necessarily limited to any one embodiment.

The electronic module region EMA may be surrounded by the active region F-AA and the peripheral region F-NAA. However, embodiments of the present disclosure are not necessarily limited thereto. For example, in an embodiment the electronic module region EMA may be disposed in the active region F-AA or may be variously arranged.

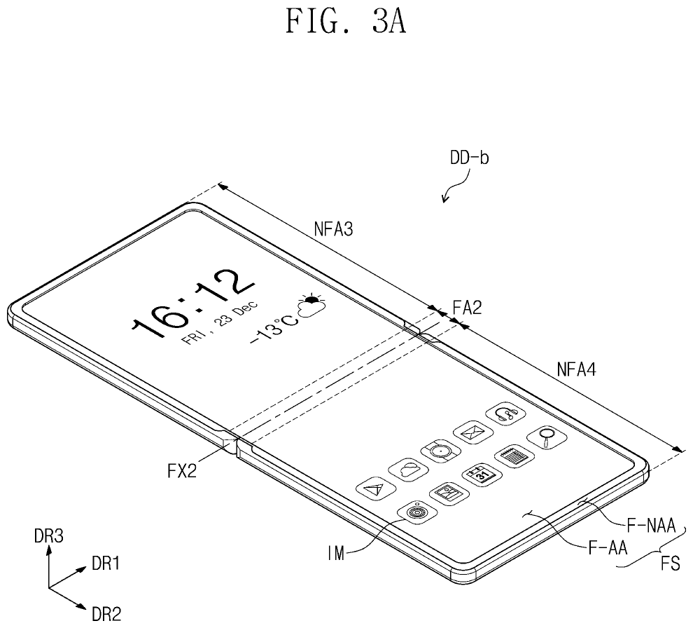

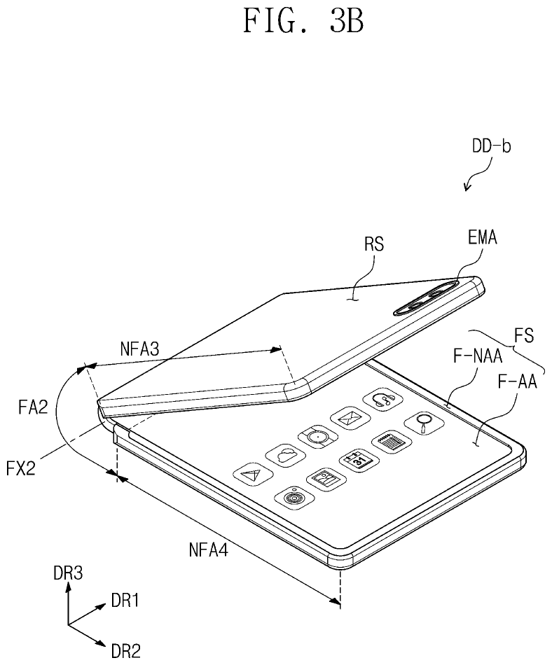

FIG. 3A is a perspective view illustrating an unfolded state of the display device according to an embodiment. FIG. 3B is a perspective view illustrating that the display device illustrated in FIG. 3A is being in-folded. FIG. 3C is a perspective view illustrating that the display device illustrated in FIG. 3A is being out-folded.

A display device DD-b according to an embodiment may be folded with respect to a second folding axis FX2 extending in one direction parallel to the first direction axis DR1. In an embodiment shown in FIG. 3B, the extension direction of the second folding axis FX2 is parallel to the extension direction of the relatively short side of the display device DD-b. However, embodiments of the present disclosure are not necessarily limited thereto.

The display device DD-b according to an embodiment may include at least one folding region FA2 and first and second non-folding regions NFA3 and NFA4 adjacent to the folding region FA2. The first and second non-folding regions NFA3 and NFA4 may be spaced apart from each other (e.g., in the second direction DR2) with the folding region FA2 therebetween.

The folding region FA2 has a predetermined curvature and a radius of curvature. In an embodiment, the display device DD-b may be in-folded so that the first non-folding region NFA3 and the second non-folding region NFA4 may face each other and the display surface FS is not exposed to the outside. In addition, referring to FIG. 3C, in an embodiment of the present disclosure, the display device DD may be out-folded so that the first display surface FS is exposed to the outside.

The display device DD-b according to an embodiment of the present disclosure may include the second display surface RS, and the second display surface RS may be defined as a surface facing at least a portion of the first display surface FS. In an embodiment, the second display surface RS may include an electronic module region EMA (FIG. 3B) in which electronic modules including various components are disposed. In addition, an image or video may be displayed on at least a part of the second display surface RS.

In the display device DD-b according to an embodiment, the first display surface FS may be visible to the user in a non-folded state, and the second display surface RS may be visible to the user in an in-folded state.

The display devices DD-a and DD-b according to an embodiment may be configured to repeatedly perform an in-folding operation or an out-folding operation from an unfolding operation. However, embodiments of the present disclosure are not necessarily limited thereto. The display device DD-a and DD-b according to an embodiment may be configured to select any one operation among an unfolding operation, an in-folding operation, and an out-folding operation. Also, in an embodiment in which the display device includes a plurality of folding regions, a folding direction of at least one of the plurality of folding regions may be different from a folding direction of the other folding regions. For example, in an embodiment in which the display device includes two folding regions, the two non-folding regions with one folding region therebetween may be in-folded, and the two non-folding regions with the other folding region therebetween may be out-folded.

Hereinafter, the description of the display device will be made based on the structure of the rigid type display device illustrated in FIG. 1. However, the following description of the display device will also be similarly applied to the foldable display device illustrated in FIGS. 2A to 3C.

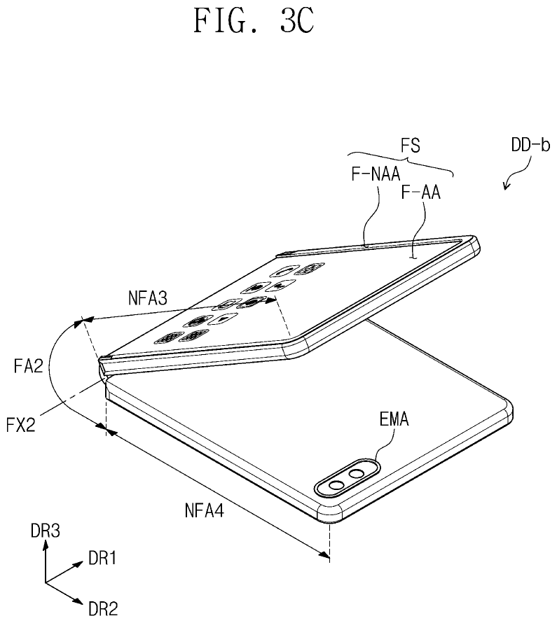

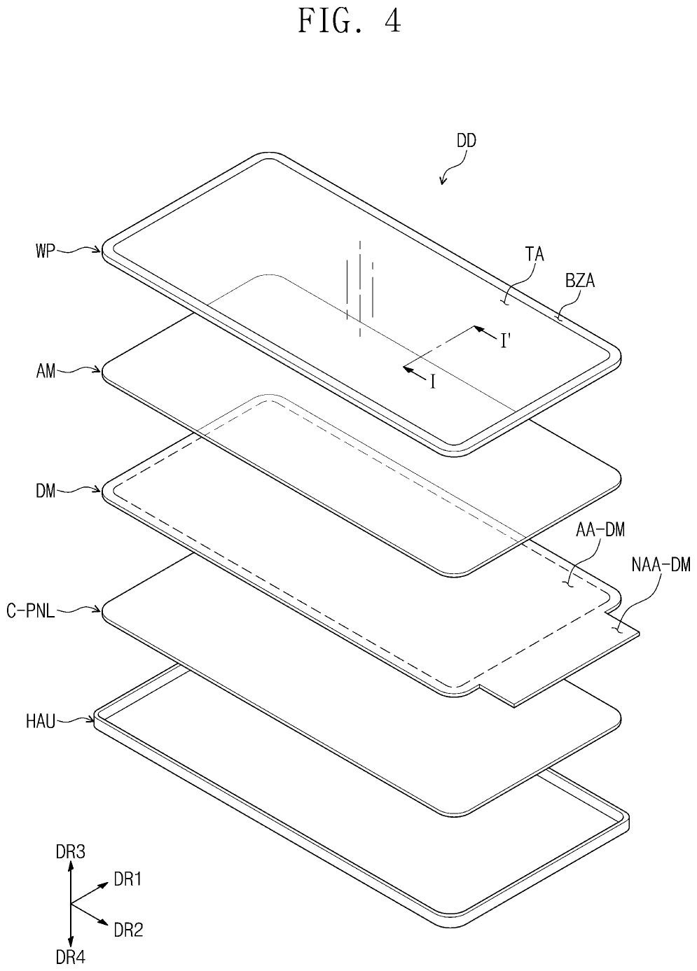

FIG. 4 is an exploded perspective view of a display device according to an embodiment. Referring to FIG. 4, the display device DD according to an embodiment may include a display module DM, a window WP disposed on the display module DM, and an adhesive member AM disposed between the display module DM and a window WP (e.g., in the third direction DR3). The display device DD according to an embodiment may further include an impact resistant layer C-PNL disposed on a rear surface of the display module DM to protect the display module DM. In addition, the display device DD according to an embodiment may further include a housing HAU in which the display module DM is accommodated.

In the display device DD illustrated in FIGS. 1 and 4, the window WP and the housing HAU may be coupled to each other form an exterior of the display device DD. The housing HAU may be disposed below the display module DM (e.g., in the fourth direction DR4). The housing HAU may include a material having relatively high rigidity. For example, in an embodiment the housing HAU may include a frame and/or plate made of glass, plastic, or metal. The housing HAU may provide a predetermined accommodation space. The display module DM may be accommodated in the accommodation space and protected from external impact.

The impact resistant layer C-PNL (e.g., an impact absorbing layer) may be disposed between the housing HAU and the display module DM (e.g., in the third direction DR3). The impact resistant layer C-PNL may prevent the display module DM from being pressed and plastically deformed due to external impacts and force. The impact resistant layer C-PNL may increase the impact resistance of the display device DD. In an embodiment, the impact resistant layer C-PNL may include sponge, foam, or an elastomer. In addition, the impact resistant layer C-PNL may be formed by including at least one of an acrylic-based polymer, a urethane-based polymer, a silicon-based polymer, or an imide-based polymer. However, embodiments of the present disclosure are not necessarily limited thereto and the materials included in the impact resistant layer C-PNL may vary.

The display module DM may be activated in response to an electrical signal. The display module DM is activated to display the image IM (FIG. 1) on the display region DA (FIG. 1) of the display device DD. An active region AA-DM and a peripheral region NAA-DM may be defined in the display module DM. The active region AA-DM may be activated in response to an electrical signal. The peripheral region NAA-DM may be a region positioned adjacent to at least one side of the active region AA-DM. A circuit or wiring for driving the active region AA-DM may be disposed in the peripheral region NAA-DM.

The adhesive member AM may bond the display module DM and the window WP to each other. In an embodiment, the adhesive member AM may be an optically clear adhesive. The adhesive member AM may be in the form of a film. The adhesive member AM may be disposed between the display module DM and the window WP (e.g., in the third direction DR3).

In an embodiment, the adhesive member AM may include a plurality of adhesive layers AP1 and AP2 (FIG. 6) having different storage moduli at low temperatures. For example, in an embodiment the adhesive layer AP1 (FIG. 6) directly adjacent to the display module DM (e.g., in the fourth direction DR4) may have a relatively small storage modulus at a low temperature. The adhesive members AP1 and AP2 (FIG. 6) according to an embodiment of the inventive concept may have a structure in which an adhesive layer having a relatively low storage modulus at a low temperature and an adhesive layer having a relatively high modulus at a low temperature are alternately stacked in a thickness direction (e.g., in the third direction DR3) from a portion adjacent to the display module DM. Accordingly, the adhesive member AM may exhibit an increased impact resistance, and the display device DD including the adhesive member AM according to an embodiment may prevent the display module DM from being damaged. In addition, in an embodiment in which the display device DD according is a foldable display device, the display device DD includes an adhesive member AM and thus exhibits excellent durability and folding characteristics at the same time. A more detailed description of the adhesive member AM will be provided later.

The window WP may include a transmission region TA and a bezel region BZA. The transmission region TA may overlap at least a portion of the active region AA-DM of the display module DM (e.g., in the third direction DR3). In an embodiment, the transmission region TA may be an optically transparent region. The image IM (FIG. 1) may be provided to the user through the transmission region TA.

The bezel region BZA may be a region having a relatively low light transmittance as compared to the transmission region TA. The bezel region BZA may define a shape of the transmission region TA. For example, the bezel region BZA may be adjacent to the transmission region TA (e.g., in the first and/or second directions DR1, DR2) and may surround the transmission region TA.

The bezel region BZA may have a predetermined color. The bezel region BZA may cover the peripheral region NAA-DM of the display module DM and may prevent the peripheral region NAA-DM from being viewed from the outside. However, an embodiment of the present disclosure is not necessarily limited to those illustrated in the drawing. For example, in an embodiment the bezel region BZA may be disposed adjacent to only one side of the transmission region TA, or at least a portion of the bezel region may be omitted.

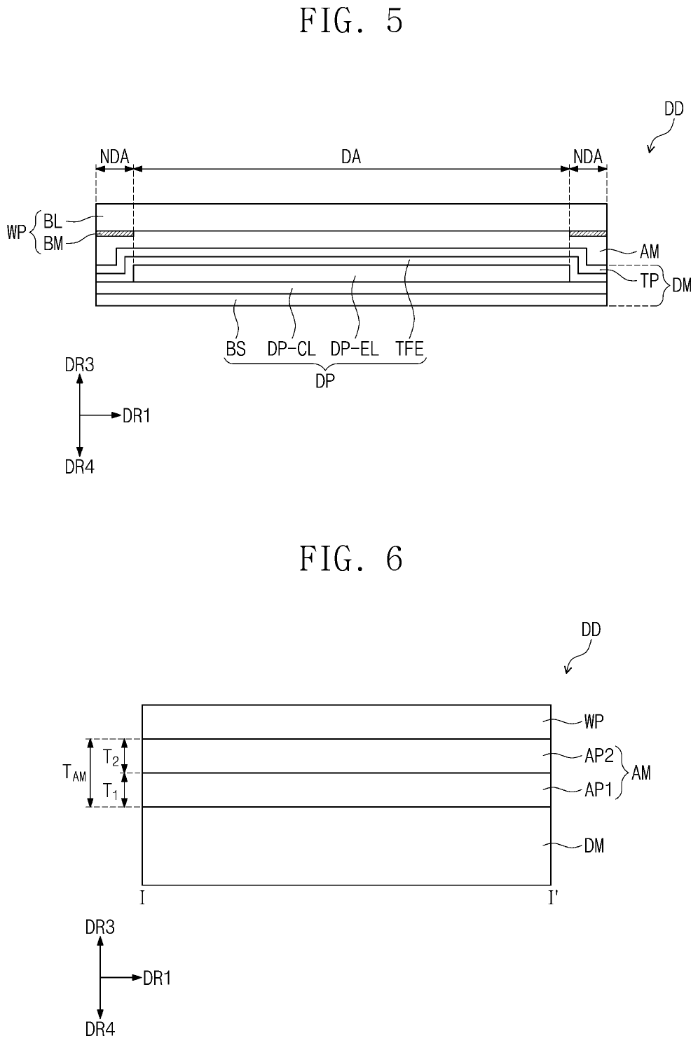

FIG. 5 is a cross-sectional view of a display device according to an embodiment. FIG. 5 is a cross-sectional view illustrating the display module DM, the adhesive member AM, and the window WP in FIG. 4.

Referring to FIG. 5, the display module DM may include a display panel DP, and an input-sensing unit TP (e.g., an input sensing layer) disposed on the display panel DP. The display panel DP may include a base substrate BS, a circuit layer DP-CL disposed on the base substrate BS (e.g., in the third direction DR3), a display element layer DP-EL disposed on the circuit layer DP-CL (e.g., in the third direction DR3), and an encapsulation layer TFE disposed on the display element layer DP-EL (e.g., in the third direction DR3). The adhesive member AM may be disposed between the display panel DP and the window WP (e.g., in the third direction DR3).

However, the configuration of the display panel DP illustrated in FIG. 5 is an example, and the configuration of the display panel DP is not necessarily limited thereto. For example, in an embodiment the display panel DP may include a liquid crystal display element, and in this embodiment the encapsulation layer TFE may be omitted.

The base substrate BS may provide a base surface on which the circuit layer DP-CL is disposed. In an embodiment, the base substrate BS may be a flexible substrate capable of bending, folding, rolling, or the like. For example, the base substrate BS may be a glass substrate, a metal substrate, or a polymer substrate. However, embodiments of the present disclosure are not limited thereto, and the base substrate BS may include an inorganic layer, an organic layer, or a composite material layer in some embodiments.

In an embodiment, the circuit layer DP-CL may include an insulating layer, a semiconductor pattern, a conductive pattern, a signal line, and the like. For example, in an embodiment the circuit layer DP-CL may include a switching transistor and a driving transistor for driving the light-emitting element of the display element layer DP-EL.

In an embodiment, the display element layer DP-EL may include a light-emitting element that emits light. For example, in an embodiment the light-emitting element may include an organic light-emitting material, an inorganic light-emitting material, an organic-inorganic light-emitting material, a quantum dot, a quantum rod, a micro LED, or a nano LED.

The encapsulation layer TFE may be disposed on the display element layer DP-EL (e.g., in the third direction DR3). The encapsulation layer TFE may protect the display element layer DP-EL from moisture, oxygen, and/or foreign substances such as dust particles. The encapsulation layer TFE may include at least one inorganic layer. In addition, the encapsulation layer TFE may include at least one organic layer and at least one inorganic layer. For example, in an embodiment the encapsulation layer TFE may include an inorganic layer, an organic layer, and an inorganic layer which are sequentially stacked (e.g., in the third direction DR3). However, embodiments of the present disclosure are not necessarily limited thereto and the number of the inorganic layers and organic layers and the arrangement thereof may vary.

The input-sensing unit TP may be disposed on the display panel DP. For example, in an embodiment the input-sensing unit TP may be disposed directly on the encapsulation layer TFE of the display panel DP. In an embodiment, the input-sensing unit TP may sense an external input, change the external input into a predetermined input signal, and provide the input signal to the display panel DP. For example, in the display device DD, the input-sensing unit TP may be a touch sensor that senses a touch. The input-sensing unit TP may recognize a user's direct touch, a user's indirect touch, a direct touch by an object, or an indirect touch by an object.

The input-sensing unit TP may sense at least one of a position or intensity (e.g., a pressure) of a touch applied from the outside. In an embodiment, the input-sensing unit TP may have various structures or be made of various materials, and is not necessarily limited to any one embodiment. The input-sensing unit TP may include a plurality of sensing electrodes for sensing an external input. The sensing electrodes may sense an external input in a capacitive manner. The display panel DP may receive the input signal from the input-sensing unit TP and generate an image corresponding to the input signal.

In an embodiment, the adhesive member AM may be disposed directly on the display module DM. For example, other components may not be disposed between the display module DM and the adhesive member AM. The window WP may be disposed directly on the adhesive member AM. For example, other components may not be disposed between the adhesive member AM and the window WP. Only the adhesive member AM may be disposed between the display module DM and the window WP. In an embodiment, a polarizing plate may not be included between the display module DM and the window WP. However, embodiments of the present disclosure are not necessarily limited thereto. For example, in an embodiment, other components may be disposed between the adhesive member AM and the display module DM or between the adhesive member AM and the window WP.

The adhesive member AM may be disposed on the display panel DP. The adhesive member AM may be disposed directly on the input-sensing unit TP that is disposed on the display panel DP. For example, other components may not be disposed between the input-sensing unit TP and the adhesive member AM. However, embodiments of the present disclosure are not necessarily limited thereto, and other components may be further disposed between the input-sensing unit TP and the adhesive member AM.

The window WP may include a base layer BL and a printed layer BM. In an embodiment, the window WP may further include at least one functional layer provided on the base layer BL. For example, in an embodiment the functional layer may be a hard coating layer, an anti-fingerprint coating layer, and the like. However, embodiments of the present disclosure are not necessarily limited thereto.

In an embodiment, the base layer BL may be a glass or plastic substrate. Alternatively, the base layer BL may be formed of a flexible polymer resin. For example, in an embodiment the base layer BL may be made of polyimide, polyacrylate, polymethylmethacrylate, polycarbonate, polyethylenenaphthalate, polyvinylidene chloride, polyvinylidene difluoride, polystyrene, ethylene vinylalcohol copolymer, or a combination thereof. However, embodiments of the present disclosure are not necessarily limited thereto.

The printed layer BM may be disposed on one surface of the base layer BL. For example, in an embodiment, the printed layer BM may be disposed on a lower surface of the base layer BL adjacent to the display module DM. The printed layer BM may be disposed on an edge region of the base layer BL. In an embodiment, the printed layer BM may be an ink-print layer. In addition, the printed layer BM may include a pigment or a dye. In the window WP, the bezel region BZA may be a region where the printed layer BM is provided.

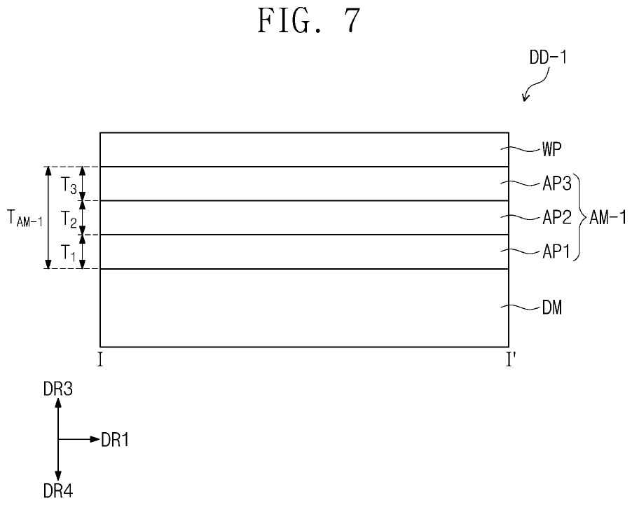

FIG. 6 is a view schematically illustrating a display device according to an embodiment. FIG. 7 is a view schematically illustrating a display device according to an embodiment.

Referring to FIG. 6, the adhesive member AM may include a first adhesive layer AP1 and a second adhesive layer AP2. The first adhesive layer AP1 may be disposed closer to the display module DM than the second adhesive layer AP2. For example, as shown in an embodiment of FIG. 6, the first adhesive layer AP1 may be disposed directly on the display module DM (e.g., in the third direction DR3). For example, other components may not be disposed between the display module DM and the first adhesive layer AP1. However, embodiments of the present disclosure are not necessarily limited thereto. For example, in an embodiment, the adhesive member AM may further include another adhesive layer disposed between the display module DM and the first adhesive layer AP1.

The second adhesive layer AP2 may be disposed between the first adhesive layer AP1 and the window WP (e.g., in the third direction DR3). The second adhesive layer AP2 may be disposed closer to the window WP than the first adhesive layer AP1. For example, in an embodiment the window WP may be disposed directly on the first adhesive layer AP2. For example, other components may not be disposed between the second adhesive layer AP2 and the window WP. However, embodiments of the present disclosure are not necessarily limited thereto. For example, in some embodiment the adhesive member AM according to an embodiment may further include another adhesive layer disposed between the window WP and the second adhesive layer AP2.

In an embodiment, the second adhesive layer AP2 may be disposed directly on the first adhesive layer AP1. For example, other components may not be disposed between the first adhesive layer AP1 and the second adhesive layer AP2. However, embodiments of the present disclosure are not necessarily limited thereto. For example, in an embodiment another adhesive layer may be further disposed between the first adhesive layer AP1 and the second adhesive layer AP2.

The first adhesive layer AP1 may have a first storage modulus at −20° C. The second adhesive layer AP2 may have a second storage modulus at −20° C. that is less than the first storage modulus. For example, the first adhesive layer AP1 adjacent to the display module DM may be a relatively low modulus layer, and the second adhesive layer AP2 adjacent to the window WP may be a relatively high modulus layer. Accordingly, the adhesive member AM may exhibit increased impact resistance by having a modulus distribution of low modulus/high modulus in the thickness direction (e.g., the third direction DR3). As a result, the display device DD including the adhesive member AM according to an embodiment may have excellent durability and may prevent damage to the display module DM from external impact. In addition, in an embodiment in which the display device DD is a foldable display device, the display device DD includes the adhesive member AM and may thus exhibit excellent durability and folding characteristics at the same time.

Hereinafter, the storage modulus described herein to is defined as a storage modulus measured at −20° C.

In an embodiment, the first storage modulus may be in a range of about 150 KPa to about 350 KPa. In a comparative embodiment in which the first storage modulus is less than about 150 KPa, the adhesive member exhibits reduced impact resistance. In a comparative embodiment in which the first storage modulus is greater than about 350 KPa, the flexibility of the adhesive member is reduced. In an embodiment in which the first storage modulus satisfies the range of about 150 KPa to about 350 KPa, the adhesive member AM according to an embodiment may exhibit increased impact resistance and flexibility. Accordingly, in the foldable display device, the display device DD including the adhesive member AM according to an embodiment may exhibit excellent durability and folding characteristics at the same time.

In an embodiment, the second storage modulus may be in a range of about 8,500 KPa to about 25,000 KPa. In a comparative embodiment in which the second storage modulus is less than about 8,500 KPa, the adhesive member exhibits reduced impact resistance properties. In a comparative embodiment in which the second storage modulus of the adhesive member AM is greater than about 25,000 KPa, the flexibility of the adhesive member AM is reduced. In an embodiment in which the second storage modulus satisfies the range of about 8,500 KPa to about 25,000 KPa, the adhesive member AM according to an embodiment may exhibit increased impact resistance and flexibility. Accordingly, in the foldable display device, the display device DD including the adhesive member AM according to an embodiment may exhibit excellent durability and folding characteristics at the same time.

In an embodiment, the adhesive member AM may have a thickness TAM in a range of about 150 μm to about 200 μm. In a comparative embodiment in which the adhesive member AM has a thickness TAM of less than about 150 μm, the adhesive member AM exhibits reduced impact resistance. In a comparative embodiment in which the thickness TAM of the adhesive member AM is greater than about 200 μm, the thickness of the display device DD increases or the adhesive member AM flows out of the display module DM and is exposed, resulting in reduced adhesion reliability. In a comparative embodiment in which the adhesive member AM is applied to a foldable display, the adhesive member AM having a thickness TAM of greater than about 200 μm exhibits reduced flexibility. In an embodiment in which the thickness TAM of the adhesive member AM satisfies the range of about 150 μm to about 200 μm, the adhesive member AM may exhibit excellent impact resistance and flexibility at the same time. In addition, the display device DD including the adhesive member AM according to an embodiment may exhibit excellent durability and adhesion reliability. Also, when the adhesive member AM is applied to a foldable display device, the adhesive member AM may exhibit excellent durability, bonding reliability, and folding characteristics at the same time.

In an embodiment, the first adhesive layer AP1 may have a thickness T₁ in a range of about 50 μm to about 100 μm. In an embodiment in which the thickness T₁ of the first adhesive layer AP1 satisfies the range of about 50 μm to about 100 μm, the adhesive member AM may exhibit excellent impact resistance and flexibility at the same time. The display device DD including the adhesive member AM according to an embodiment may exhibit excellent durability and folding characteristics at the same time.

In an embodiment, the second adhesive layer AP2 may have a thickness T₂ in a range of about 50 μm to about 150 μm. In an embodiment in which the thickness T₂ of the second adhesive layer AP2 satisfies the range of about 50 μm to about 150 μm, the adhesive member AM may exhibit excellent impact resistance and flexibility at the same time. The display device DD including the adhesive member AM according to an embodiment may exhibit excellent durability and folding characteristics at the same time.

In an embodiment, the first adhesive layer AP1 may have a thickness T₁ in a range of about 50 μm to about 100 μm, and the second adhesive layer AP2 may have a thickness T₂ in a range of about 50 μm to about 150 μm. In an embodiment in which the thickness T₁ of the first adhesive layer AP1 is in a range of about 50 μm to about 100 μm, and the thickness T₂ of the second adhesive layer AP2 is in a range of about 50 μm to about 150 μm, the adhesive member AM according to an embodiment may exhibit excellent impact resistance and flexibility at the same time.

A loss tangent of each of the first adhesive layer AP1 and the second adhesive layer AP2 may be greater than or equal to about 1. Accordingly, the adhesive member AM according to an embodiment may exhibit excellent impact resistance.

Referring to FIG. 7, the adhesive member AM-1 according to an embodiment may further include a third adhesive layer AP3 disposed between the second adhesive layer AP2 and the window WP (e.g., in the third direction DR3). The third adhesive layer AP3 may be closer to the window WP than the second adhesive layer AP2. In an embodiment, the window WP may be disposed directly on the third adhesive layer AP3. For example, other components may not be disposed between the third adhesive layer AP3 and the window WP. However, embodiments of the present disclosure are not necessarily limited thereto. For example, in an embodiment, another adhesive layer may be further disposed between the window WP and the third adhesive layer AP3.

The third adhesive layer AP3 may be disposed directly on the second adhesive layer AP2 (e.g., in the third direction DR3). For example, other components may not be disposed between the second adhesive layer AP2 and the third adhesive layer AP3. However, embodiments of the present disclosure are not necessarily limited thereto. For example, in an embodiment, another adhesive layer may be further disposed between the second adhesive layer AP2 and the third adhesive layer AP3.

The third adhesive layer AP3 may have a third storage modulus at −20° C. that is less than the second storage modulus. Accordingly, the adhesive member AM-1 according to an embodiment may exhibit excellent impact resistance having a modulus distribution of low modulus/high modulus/low modulus in the thickness direction (e.g., the third direction DR3). In an embodiment, the third storage modulus may be the same as or different from the first storage modulus.

In an embodiment, the third storage modulus may be in a range of about 150 KPa to about 350 KPa. In a comparative embodiment in which the third storage modulus is less than about 150 KPa, the adhesive member exhibits reduced impact resistance. In a comparative embodiment in which the third storage modulus is greater than about 350 KPa, the flexibility of the adhesive member is reduced. In an embodiment in which the third storage modulus satisfies the range of about 150 KPa to about 350 KPa, the adhesive member AM-1 according to an embodiment may exhibit excellent impact resistance and flexibility. Accordingly, in the foldable display device, the display device DD-1 including the adhesive member AM-1 according to an embodiment may exhibit excellent durability and folding characteristics at the same time.

In an embodiment, the adhesive member AM-1 according to an embodiment may have a thickness T_{AM-1} in a range of about 150 μm to about 200 μm. In a comparative embodiment in which the thickness T_{AM-1} of the adhesive member AM-1 is less than about 150 μm, the adhesive member AM-1 exhibits reduced impact resistance. In a comparative embodiment in which the adhesive member AM-1 has a thickness T_{AM-1} of greater than about 200 μm, the thickness of the display device DD increases. In a comparative embodiment in which the adhesive member AM-1 is applied to a foldable display device and the thickness T_{AM-1} of the adhesive member AM-1 exceeds about 200 μm, the adhesive member AM-1 exhibits inferior flexibility. In an embodiment, in which the thickness T_{AM-1} of the adhesive member AM-1 satisfies the range of about 150 μm to about 200 μm, the adhesive member AM-1 may exhibit excellent impact resistance and flexibility at the same time. In addition, the display device DD-1 including the adhesive member AM-1 according to an embodiment may exhibit excellent durability and folding characteristics at the same time.

In an embodiment, the third adhesive layer AP3 may have a thickness T₃ in a range of about 50 μm to about 75 μm. In an embodiment in which the thickness T₃ of the third adhesive layer AP3 satisfies the range of about 50 μm to about 75 μm, the adhesive member AM-1 according to an embodiment may exhibit excellent impact resistance and flexibility at the same time.

In an embodiment, the thickness T₁ of the first adhesive layer AP1 may be in a range of about 50 μm to about 75 μm, the thickness T₂ of the second adhesive layer AP2 may be in a range of about 50 μm to about 100 μm, and the thickness T₃ of the first adhesive layer AP3 may be in a range of about 50 μm to about 75 μm. In an embodiment in which the thickness range is satisfied such that the thickness T₁ of the first adhesive layer AP1 is about 50 μm to about 75 μm, the thickness T₂ of the second adhesive layer AP2 is about 50 μm to about 100 μm, and the thickness T₃ of the first adhesive layer AP3 is about 50 μm to about 75 μm, the adhesive member AM-1 may exhibit excellent impact resistance and flexibility at the same time. The display device DD-1 including the adhesive member AM-1 according to an embodiment may exhibit excellent durability and folding characteristics at the same time.

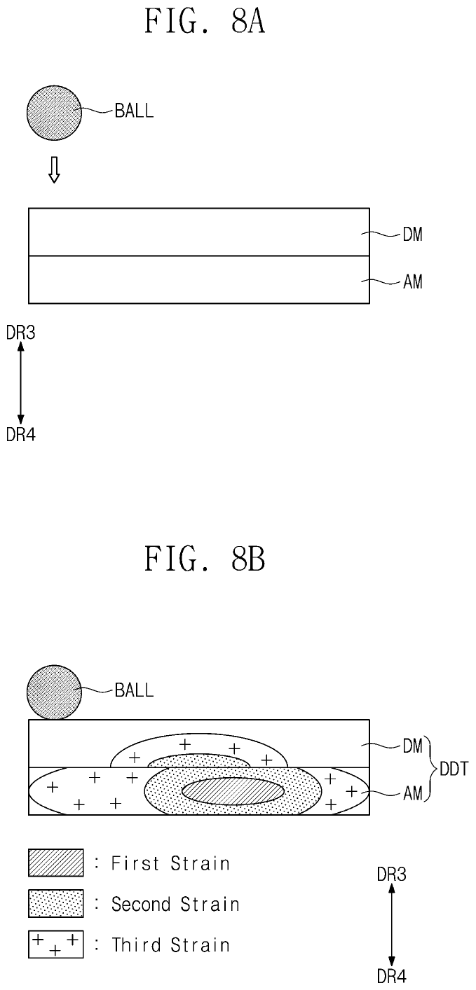

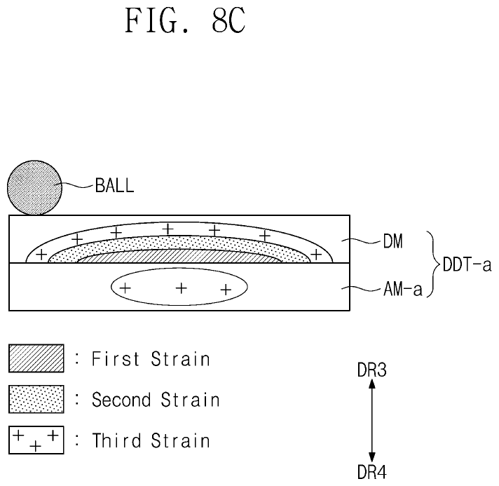

FIG. 8A is a view schematically illustrating a ball that is dropped onto a display module. FIG. 8B is a view schematically illustrating a ball that has been dropped onto a test display device according to Examples according to embodiments of the present disclosure. FIG. 8C is a view schematically illustrating a ball that has been dropped onto a test display device according to a Comparative Example.

### (Conditions of Ball Drop Test 1)

Test display devices DDT (FIG. 8B) and DDT-a (FIG. 8C) have structures in which the display module DM and the adhesive members AM and AM-a are combined, respectively. The display module DM used in the test display devices DDT and DDT-a has a stacked structure of the display module DM (FIG. 4). As illustrated in FIG. 6 or 7, the adhesive member AM used in the test display device DDT includes a plurality of adhesive layers AP1 to AP2 or AP1 to AP3 (FIGS. 6 and 7) and has a low/high modulus distribution or a low/high/low modulus distribution. The low modulus adhesive layer has a storage modulus of about 175 KPa at −20° C., and the high modulus adhesive layer has a storage modulus of about 8,517 KPa at −20° C. The adhesive member AM-a according to a Comparative Example used in the test display device DDT-a is an adhesive member provided as a single layer. The adhesive member AM-a according to the Comparative Example has a storage modulus of about 23,000 KPa at −20° C.

The thicknesses of the adhesive members according to Examples according to embodiments of the present disclosure and the Comparative Example used in the test are each about 150 μm.

A ball used in the ball drop test has a weight of about 0.5 g, and was dropped onto the display module from a height of about 5 cm above the display module.

### (Evaluation Criteria of Ball Drop Test 1)

The ball drop test illustrated in FIGS. 8A to 8C is a test for confirming the durability of a display device and the impact resistance of an adhesive member. As the strain of the display module is less and the strain of the adhesive member is greater, the impact resistance of the adhesive member and the durability of the display device are increased. As the strain of the display module is greater and the strain of the adhesive member is less, the impact resistance of the adhesive member and the durability of the display device are decreased. The magnitude relationship among the first strain to the third strain is first strain>second strain>third strain.

### (Evaluation Results of Ball Drop Test 1)

Referring to FIG. 8B, when a ball is dropped onto the test display device DDT according to an Example according to an embodiment of the present disclosure, the display module DM has a maximum second strain and the adhesive member AM has a maximum first strain, and thus it may be confirmed that the strain of the adhesive member AM is greater than the strain of the display module DM. This may demonstrate that the adhesive member AM according to an Example according to an embodiment of the present disclosure exhibits excellent impact resistance, and the test display device DDT including the adhesive member AM according to Example exhibits excellent durability.

Referring to FIG. 8C, when a ball is dropped onto the test display device DDT-a according to a Comparative Example, the display module DM has a maximum first strain and the adhesive member has a maximum third strain, and thus it may be confirmed that the strain of the adhesive member AM-a is less than the strain of the display module DM. This may demonstrate that the adhesive member AM-a according to a Comparative Example exhibits reduced impact resistance, and the test display device DDT-a including the adhesive member AM-a according to a Comparative Example exhibits reduced durability.

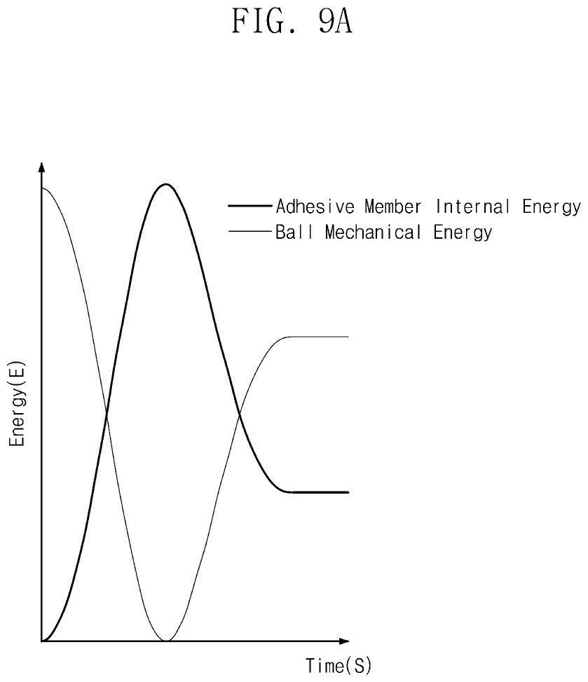

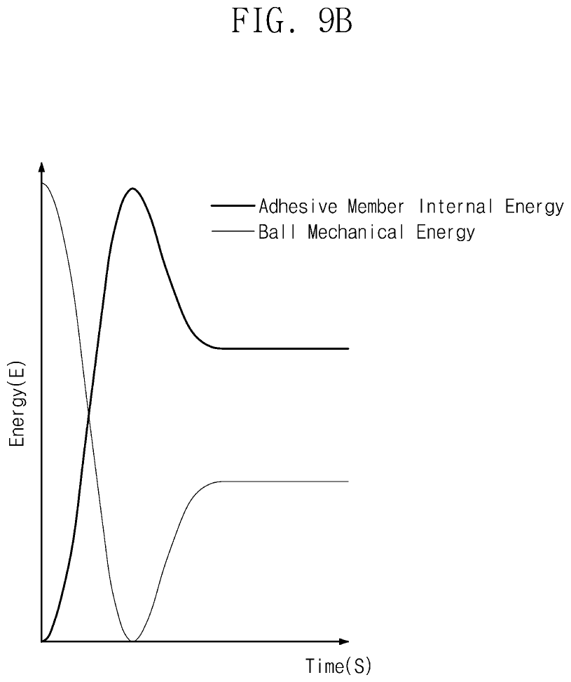

FIG. 9A is a view illustrating the amount of change in internal energy of a test display device according to an Example before and after a ball drop according to an embodiment of the present disclosure. FIG. 9B is a view illustrating the amount of change in internal energy of a test display device according to a Comparative Example before and after a ball drop. The test display device according to an Example may be the test display device illustrated in FIG. 8B. The test display device according to a Comparative Example may be the test display device illustrated in FIG. 8C.

Referring to FIGS. 8B, 8C, 9A and 9B together, in the test display device according to an Example, it may be confirmed that the proportion of the mechanical energy of the ball, which is converted into the internal energy of the adhesive member, is relatively small compared to the test display device according to the Comparative Example. This means that in the test display device according to the Example according to an embodiment of the present disclosure, the proportion of the mechanical energy of the ball, transferred from the outside, is lost in the form of vibrational energy or thermal energy due to the adhesive member is relatively large. For example, as the proportion of the mechanical energy of a ball, which is converted into the internal energy of the adhesive member is less, the impact resistance of the adhesive member increases. Accordingly, the adhesive member according to the Example according to an embodiment of the present disclosure may have excellent impact resistance, and the test display device including the adhesive member according to the Example according to an embodiment of the present disclosure may exhibit excellent durability.

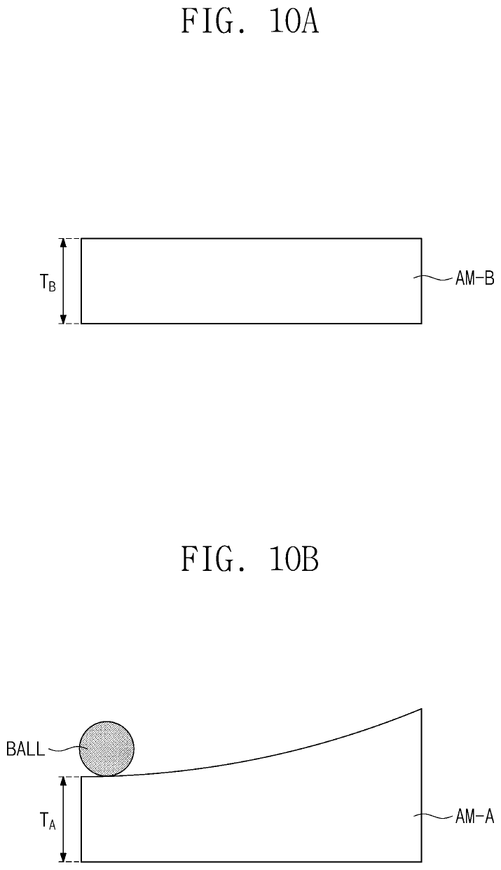

FIG. 10A is a view illustrating an undeformed adhesive member before a ball drop. FIG. 10B is a view illustrating a deformed adhesive member after a ball drop. Hereinafter, ball drop test 2 will be described below with reference to FIGS. 10A and 10B.

### (Conditions of Ball Drop Test 2)

As illustrated in an embodiment of FIG. 6, the adhesive member AM according to an Example (“Example 1”) according to an embodiment of the present disclosure includes two adhesive layers AP1 and AP2 (FIG. 6) and has a low/high modulus distribution. The low modulus adhesive layer has a storage modulus of about 175 KPa at −20° C., and the high modulus adhesive layer has a storage modulus of about 8,517 KPa at −20° C. The thickness of the low modulus adhesive layer is about 50 μm, and the thickness of the high modulus adhesive layer is about 100 μm.

As illustrated in an embodiment of FIG. 7, the adhesive member AM-1 according to an Example (“Example 2”) according to an embodiment of the present disclosure includes three adhesive layers AP1 to AP3 (FIG. 7) and has a modulus distribution of low modulus/high modulus/low modulus. The low modulus adhesive layer has a thickness of about 37.5 μm, and the high modulus adhesive layer has a thickness of about 75 μm.

The adhesive member according to a Comparative Example is an adhesive member provided in one layer. The adhesive member according to a Comparative Example has a storage modulus of about 25,000 KPa at −20° C. The thickness of the adhesive member according to the Comparative Example is about 150 μm.

A ball used in the ball drop test had a weight of about 0.5 g, and was dropped onto the adhesive member from a height of about 5 cm above the adhesive member.

### (Evaluation Criteria of Ball Drop Test 2)

A difference between the thickness Ty of the adhesive member AM-B before the ball drop and the thickness TA of the adhesive member AM-A after the ball drop is measured to test the pressing amount of the adhesive member. When the pressing amount of the adhesive member is about 30% or more, the impact resistance is excellent.

$$Pressed amount ( \% ) = ( ( {T}_{A} - {T}_{B} ) / {T}_{A} ) * 100$$

### (Evaluation Results of Ball Drop Test 2)

TABLE 1

| | Comparative | | |
|---|---|---|---|
| Division | Example | Example 1 | Example 2 |
| Thickness of adhesive member | 0.150 | 0.150 | 0.150 |
| before ball drop (nm) | | | |
| Thickness of adhesive member | 0.121698 | 0.099711 | 0.073976 |
| after ball drop (nm) | | | |
| Pressing amount of adhesive | 18.87% | 33.53% | 35.95% |
| member (%) | | | |

Referring to the results of Table 1, it may be confirmed that the pressing amount of the adhesive member according to the Comparative Example was less than about 30%, and the pressing amount of the adhesive members according to Examples 1 and 2 was greater than about 30%. This may demonstrate that the adhesive member according to Examples 1 and 2 according to embodiments of the present disclosure have a structure in which a low modulus adhesive layer and a high modulus adhesive layer are alternately stacked, thereby exhibiting excellent impact resistance.

A display device according to an embodiment of the present disclosure does not include a polarizing plate, and has a structure in which a display module, an adhesive member, and a window are sequentially stacked. An adhesive member according to an embodiment includes a low modulus adhesive layer adjacent to a display module, and a high modulus adhesive layer disposed on the low modulus adhesive layer. The adhesive member according to an embodiment exhibits excellent impact resistance. For example, the adhesive member according to an embodiment may prevent damage to the display panel from external impact. A display device according to an embodiment may exhibit excellent durability by including an adhesive member exhibiting excellent impact resistance.

A display device according to an embodiment of the present disclosure may include an adhesive member that has a first adhesive layer having a first modulus at −20° C., and a second adhesive layer disposed on the first adhesive layer and having a second modulus at −20° C., and thus may exhibit excellent resistance.

Although embodiments of the present disclosure have been described, it is understood that the present disclosure should not be limited to these embodiments but various changes and modifications can be made by one ordinary skilled in the art within the spirit and scope of the present disclosure.

Therefore, the technical scope of the present disclosure should not be limited to the contents described in the detailed description of the specification.

What is claimed is:

1. A display device comprising:
a display module;
an adhesive member disposed directly on the display module; and
a window disposed directly on the adhesive member,
wherein the adhesive member includes
a first adhesive layer disposed adjacent to the display module and having a first storage modulus at −20° ° C., and
a second adhesive layer disposed directly on the first adhesive layer and having a second storage modulus at −20° C., the second storage modulus is greater than the first storage modulus.

2. The display device of claim 1, wherein the first storage modulus at −20° C. is in a range of about 150 KPa to about 350 KPa.

3. The display device of claim 1, wherein the second storage modulus at −20° C. is in a range of about 8,500 KPa to about 25,000 KPa.

4. The display device of claim 1, wherein the adhesive member has a thickness in a range of about 150 μm to about 200 μm.

5. The display device of claim 1, wherein the first adhesive layer has a thickness in a range of about 50 μm to about 100 μm.

6. The display device of claim 1, wherein the second adhesive layer has a thickness in a range of about 50 μm to about 150 μm.

7. The display device of claim 1, wherein:
the display module comprises a display panel, and an input-sensing unit disposed on the display panel; and
the adhesive member is disposed directly on the input-sensing unit.

8. The display device of claim 7, further comprising an impact absorbing layer disposed below the display panel.

9. The display device of claim 1, wherein:
the adhesive member further includes a third adhesive layer disposed between the second adhesive layer and the window and having a third storage modulus at −20° C., the third storage modulus is less than the second storage modulus.

10. The display device of claim 9, wherein the third storage modulus at −20° C. is in a range of about 150 KPa to about 350 KPa.

11. The display device of claim 9, wherein:
the first adhesive layer has a thickness in a range of about 50 μm to about 75 μm,
the second adhesive layer has a thickness in a range of about 50 μm to about 100 μm; and
the third adhesive layer has a thickness in a range of about 50 μm to about 75 μm.

12. The display device of claim 9, wherein third adhesive layer is disposed directly on the second adhesive layer.

13. The display device of claim 1, wherein the display device does not include a polarizing plate.

14. The display device of claim 1, wherein the first adhesive layer and the second adhesive layer each have a loss tangent greater than or equal to about 1.

15. A display device including a folding region that is foldable with respect to a virtual folding axis extending in a first direction, and a first non-folding region and a second non-folding region that are spaced apart from each other in a second direction perpendicular to the first direction with the folding region therebetween, the display device comprising:
a display panel;
an adhesive member disposed on the display panel; and
a window disposed directly on the adhesive member,
wherein the adhesive member includes:
a first adhesive layer adjacent to the display module and having a first storage modulus at −20° ° C., and
a second adhesive layer disposed directly on the first adhesive layer and having a second storage modulus at −20° C., the second storage modulus is greater than the first storage modulus.

16. The display device of claim 15, further comprising:
an input sensing layer disposed between the display panel and the adhesive member,
wherein the adhesive member is disposed directly on the input sensing layer.

17. The display device of claim 15, wherein the first storage modulus at −20° C. is in a range of about 150 KPa to about 350 KPa.

18. The display device of claim 15, wherein the second storage modulus at −20° C. is in a range of about 8,500 KPa to about 25,000 KPa.

19. The display device of claim 15, wherein:
the adhesive member has a thickness in a range of about 150 μm to about 200 μm;
the first adhesive layer has a thickness in a range of about 50 μm to about 100 μm; and
the second adhesive layer has a thickness in a range of about 50 μm to about 150 μm.

20. The display device of claim 15, wherein:
the adhesive member further includes a third adhesive layer disposed between the second adhesive layer and the window and having a third storage modulus at −20° C., the third storage modulus is less than the second storage modulus; and
the third adhesive layer is disposed directly on the second adhesive layer.

21. The display device of claim 20, wherein the third storage modulus at −20° C. is in a range of about 150 KPa to about 350 KPa.

22. The display device of claim 21, wherein:
the first adhesive layer has a thickness in a range of about 50 μm to about 75 μm;
the second adhesive layer has a thickness in a range of about 50 μm to about 100 μm; and
the third adhesive layer has a thickness in a range of about 50 μm to about 75 μm.
